(19) United States
(12) Patent Application Publication
(10) Pub. No.: US 2026/0287270 A1
(43) Pub. Date: Sep. 24, 2026

(54) HEAT PIPE

(71) Applicant: Fujikura Ltd., Tokyo (JP)

(72) Inventors: Randeep Singh, Tokyo (JP); Takeshi Koshio, Sakura-shi (JP); Yoji Kawahara, Tokyo (JP); Tsuyoshi Ogawa, Tokyo (JP); Ichiro Terunuma, Sakura-shi (JP); Takahiro Suga, Sakura-shi (JP)

(73) Assignee: Fujikura Ltd., Tokyo (JP)

(21) Appl. No.: 19/472,480

(22) PCT Filed: Apr. 4, 2024
(86) PCT No.: PCT/JP2024/013978

§ 371 Date: Oct. 3, 2025

(30) Foreign Application Priority Data
Apr. 5, 2023 (JP) 2023-061165

(51) Int. Cl. F28D 15/04

(52) U.S. Cl. CPC F28D 15/04

(57) ABSTRACT

A heat pipe includes: a container in which working fluid is sealed; and a wick accommodated in the container. The container includes: an accommodation portion that accommodates the wick and the working fluid; and an electrical connection portion at a position different from the accommodation portion in a longitudinal direction of the container.

### TECHNICAL FIELD

The present invention relates to a heat pipe.

The present application claims priority with respect to Japanese Patent Application No. 2023-061165 filed in Japan on Apr. 5, 2023, the contents of which are incorporated herein by reference.

### BACKGROUND

In a connection portion that electrically connects two members, Joule heat may be generated due to resistance of the connection portion. For example, an electronic component unit shown in Patent Document 1 includes a heat absorbing plate and a heat pipe, in order to absorb heat in an electrical connection portion between a connection terminal of a bus bar and a lead wire of an electronic component.

### PATENT LITERATURE

Patent Document 1: Japanese Unexamined Patent Application, First Publication No. H9-126669

In a configuration of Patent Document 1, since both the heat pipe for heat transfer and the electrical connection portion between two members are disposed in the electronic component unit, there are cases where the size of the electronic component unit having a cooling function increases.

### SUMMARY

One or more embodiments of the present invention provide a heat pipe capable of cooling an electrical connection portion in a more space-saving manner.

A first aspect of the present invention is a heat pipe including a container in which a working fluid is sealed, and a wick accommodated in the container, in which the container has an accommodation portion that accommodates the wick and the working fluid, and an electrical connection portion that is disposed at a position different from the accommodation portion in a longitudinal direction.

In this configuration, with circulation of the working fluid sealed inside the accommodation portion in contact with the electrical connection portion, while the first member and the second member are electrically connected to each other in the electrical connection portion, the heat from the electrical connection portion can be efficiently transferred to the first end part of the heat pipe.

A second aspect of the present invention is the heat pipe according to the first aspect, in which the length of the electrical connection portion in the longitudinal direction is 5 mm or more.

A third aspect of the present invention is the heat pipe according to the first aspect or the second aspect, in which a wall thickness of the container in the accommodation portion decreases as a distance from the electrical connection portion increases.

A fourth aspect of the present invention is the heat pipe according to any one of the first to third aspects, in which a cross sectional area of an internal space of the wick in a transverse section orthogonal to the longitudinal direction increases as a distance from the electrical connection portion increases.

A fifth aspect of the present invention is the heat pipe according to any one of the first to fourth aspects, in which an inner surface of the accommodation portion has a tapered shape in a cross section along the longitudinal direction.

### Advantageous Effects of Invention

According to the above aspects of the present invention, the heat pipe capable of cooling the electrical connection portion in a more space-saving manner can be provided.

### BRIEF DESCRIPTION OF THE DRAWINGS

FIG. 1 is a cross sectional view of a heat pipe according to first embodiments.

FIG. 2 is a cross sectional view of a heat pipe according to second embodiments.

FIG. 3 is a cross sectional view of a heat pipe according to a modification example of the first and second embodiments.

### DETAILED DESCRIPTION

### First Embodiments

Hereinafter, a configuration of a heat pipe 1 of one or more embodiments will be described with reference to drawings.

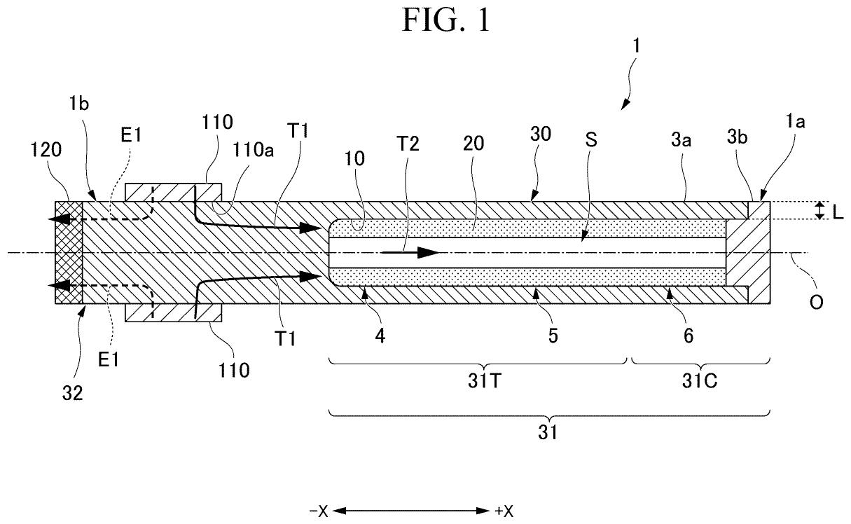

As shown in FIG. 1, the heat pipe 1 includes a wick 20 and a container 30. The container 30 has an elongated shape extending in one direction. The wick 20 is accommodated in the container 30. A working fluid (not shown) is sealed in the container 30.

The container 30 has an accommodation portion 31 that accommodates the wick 20 and the working fluid, and an electrical connection portion 32 that is disposed at a position different from the accommodation portion 31.

In the heat pipe 1 of one or more embodiments, the electrical connection portion 32 functions as a terminal that electrically connects a first member 110 and a second member 120, and the accommodation portion 31 functions as a heat transfer element that transfers heat of the electrical connection portion 32 by using latent heat of the working fluid sealed in the container 30.

FIG. 1 shows only a part of the first member 110 and the second member 120 for description.

In the heat pipe 1, an end part in which the accommodation portion 31 is provided is referred to as a first end part 1a, and an end part in which the electrical connection portion 32 is provided, which is on an opposite side of the first end part, is referred to as a second end part 1b.

### Direction Definition

In the present specification, the direction in which the container 30 extends is simply referred to as a longitudinal direction X. In the longitudinal direction X, a direction from the second end part 1b toward the first end part 1a is referred to as a +X direction, and a direction from the first end part la toward the second end part 1b is referred to as a −X direction. In a transverse sectional view of the container 30 orthogonal to the longitudinal direction X, a direction orthogonal to a central axis line O is referred to as a radial direction, and a direction of revolving around the central axis line O is referred to as a circumferential direction.

As shown in FIG. 1, the container 30 has a columnar shape. The container 30 includes a container main body 3a and a sealing portion 3b. An inner hole 10 extending from the first end part la in the −X direction is formed in the container main body 3a. The inner hole 10 is formed in the accommodation portion 31, and is not formed in the electrical connection portion 32. An end part of the inner hole 10 on a side in the +X direction is airtightly sealed by the sealing portion 3b. In order to airtightly seal a gap between the container main body 3a and the sealing portion 3b, a sealing member (not shown) such as an O-ring or the like may be disposed between the container main body 3a and the sealing portion 3b.

The sealing of the first end part la of the heat pipe 1 is not limited to the method using the sealing portion 3b. The end part of the container main body 3a on the side in the +X direction may be deformed to airtightly seal the inner hole 10. In this case, the container 30 may not have the sealing portion 3b.

In the longitudinal direction X, an outer diameter of the container 30 and a diameter of the inner hole 10 are substantially constant.

A material of the container 30 can be selected as appropriate, depending on a condition such as a working fluid type or a use temperature. For example, the container 30 is made of a metal such as copper, steel, or aluminum. In particular, in a case where a metal material having high thermal conductivity and high electrical conductivity, such as copper or aluminum, is used, heat transfer properties and thermal diffusivity in the accommodation portion 31 can be improved, and electricity can be conducted in the electrical connection portion 32. In one or more embodiments, copper is used as the material of the container 30.

### Electrical Connection Portion 32

The electrical connection portion 32 has a columnar shape extending in the longitudinal direction X and is solid. That is, in a cross section orthogonal to the longitudinal direction X, the entire surface of the electrical connection portion 32 is made of the metal of which the container 30 is made. A length of the electrical connection portion 32 in the longitudinal direction X is, for example, 5 mm or more. A proportion of the length of the electrical connection portion 32 in the longitudinal direction X to a total length of the heat pipe 1 in the longitudinal direction X may be 25 to 50%. Although details will be described below, the length of the electrical connection portion 32 in the longitudinal direction X is a length that allows the first member 110 and the second member 120 to be electrically connected to each other.

### Accommodation Portion 31

The accommodation portion 31 has a cylindrical shape whose both ends in the

longitudinal direction X are sealed. The accommodation portion 31 is not a separate body from the electrical connection portion 32, and the accommodation portion 31 and the electrical connection portion 32 are integrally formed in the container 30.

A thickness (hereinafter, referred to as wall thickness of the container 30) L of the container 30 in the radial direction in the accommodation portion 31 is, for example, 0.2 mm or more.

The working fluid is sealed in the inner hole 10 of the accommodation portion 31. The working fluid is a known heat transfer medium whose phase can be changed, and the phase of the working fluid changes between a liquid phase and a gas phase in the inner hole 10. As the working fluid, for example, water, alcohol, ammonia, chlorofluorocarbon substitutes, and the like can be employed. The working fluid type may be changed as appropriate according to a temperature range of the heat transferred by the heat pipe 1 or a transferred amount thereof. In the present specification, the working fluid in the liquid phase may be referred to as “working liquid”, and the working fluid in the gas phase may be referred to as “vapor”. Further, in a case where the liquid phase and the gas phase are not particularly distinguished, the liquid phase and the gas phase are simply described as the working fluid.

The wick 20 is disposed in the inner hole 10. In the longitudinal direction X, the wick 20 extends over a total length of the inner hole 10. The wick 20 is formed in an annular shape along an inner peripheral surface of the accommodation portion 31. An internal space S is formed on an inner side of the wick 20 in the radial direction. The wick 20 may not be formed in a partial region of the inner peripheral surface of the accommodation portion 31.

The wick 20 has a large number of fine holes capable of causing the working fluid of the liquid phase to generate a capillary force. These fine holes are used as a liquid flow passage through which the working liquid flows, and are a reflux flow passage (hereinafter, referred to as “flow passage”) for refluxing the working liquid from a condensation portion 6 to an evaporation portion 4 described below. The working liquid in the flow passage flows in the longitudinal direction X and the circumferential direction due to the capillary force.

The wick 20 is formed by, for example, bundling a plurality of thin metal wires such as thin copper wires. The thin copper wire is a linear body extending in the longitudinal direction X of the container 30. An outer diameter of the thin copper wire is, for example, several um to several hundred um. Fine holes extending in the longitudinal direction X are formed between the thin copper wires. These fine holes are used as the above liquid flow passage. Further, with movement of the working liquid between the fine holes extending in the longitudinal direction X, the working liquid also flows in the circumferential direction of the heat pipe 1.

The wick 20 is not limited to the thin metal wire, and may be a metal mesh (network body), a sintered body of metal powder, and the like, or may be a mixture thereof.

Exemplary examples of the metal configuring the wick 20 include copper, aluminum, stainless steel, and an alloy thereof. The wick 20 is not limited to being configured of metal, and may be configured of a carbon material and the like. For example, the wick 20 may be configured of a thin carbon wire, a carbon mesh, and the like.

The accommodation portion 31 includes a heat transfer portion 31T, and a cooling portion 31C provided on the side in the +X direction with respect to the heat transfer portion 31T. The heat transfer portion 31T causes the heat generated in the electrical connection portion 32 to move toward the cooling portion 31C. The cooling portion 31C releases the heat transferred by the heat transfer portion 31T to an outer side of the heat pipe 1. A heat dissipation structure (not shown) may be disposed on an outer side of the cooling portion 31C in the radial direction. The heat dissipation structure is, for example, a heat sink.

The heat transfer portion 31T includes the evaporation portion 4 in which the working liquid is evaporated to generate the vapor, and an intermediate portion 5 that causes the vapor generated in the evaporation portion 4 to move toward the cooling portion 31C. The cooling portion 31C has the condensation portion 6 in which the vapor generated in the evaporation portion 4 is condensed to generate the working liquid. In the accommodation portion 31, the evaporation portion 4, the intermediate portion 5, and the condensation portion 6 are provided side by side in this order toward the +X direction.

### Electrical Connection Between First Member 110 and Second Member 120 and Heat Transfer Cycle by Heat Pipe 1

The electrical connection portion 32 is a rod whose entire surface is made of metal in the cross section orthogonal to the longitudinal direction X, has high electrical conductivity, and electrically connects the first member 110 and the second member 120. The first member 110 is, for example, a bus bar. The second member 120 is a device that generates or receives an electric current, and is, for example, a battery or an electronic component.

More specifically, in one or more embodiments, the electrical connection portion 32 penetrates a hole 110a of the first member 110, and an outer peripheral surface of the electrical connection portion 32 is in contact with an inner surface of the hole 110a of the first member 110. An end surface of the electrical connection portion 32 on a side in the-X direction is in contact with the second member 120. For example, a hole having a circular opening may be formed in the second member 120, and the electrical connection portion 32 having the columnar shape may be inserted into the hole.

With mechanical fastening of the first member 110 and the second member 120 via the electrical connection portion 32, the electrical connection portion 32 is electrically connected to the two members 110 and 120 and serves as a terminal that passes the electric current flowing between the two members 110 and 120. The first member 110 and the electrical connection portion 32, and the second member 120 and the electrical connection portion 32 may be each electrically connected to each other by soldering.

In one or more embodiments, the electric current flows from the first member 110 to the second member 120 via the electrical connection portion 32 in a direction of an arrow E1 shown in FIG. 1. In this case, Joule heat is generated between the first member 110 and the second member 120 due to resistance at a time of connection. For example, on a connection surface between the first member 110 and the electrical connection portion 32 and a connection surface between the second member 120 and the electrical connection portion 32, Joule heat is generated due to the resistance on the connection surfaces. Hereinafter, details of the movement of heat will be described.

The heat generated on the connection surface between the first member 110 and the electrical connection portion 32 moves in a direction of an arrow T1 shown in FIG. 1 in the electrical connection portion 32, moves in a direction of an arrow T2 by the working liquid sealed in the accommodation portion 31, and is further transferred toward the outside of the heat pipe 1 in the cooling portion 31C.

More specifically, the heat is conducted toward the accommodation portion 31, from the connection surface of the first member 110 and the electrical connection portion 32. With the heat conducted to the accommodation portion 31, the working liquid permeating into the flow passage of the wick 20 of the evaporation portion 4 is heated and evaporated, and becomes the vapor.

The vapor generated in the evaporation portion 4 flows through the internal space S toward the condensation portion 6 having a lower pressure and temperature than the evaporation portion 4. In the condensation portion 6, with cooling of the container 30 by the heat dissipation structure, part of the vapor is condensed to be the working liquid. The working liquid generated in the condensation portion 6 permeates into the flow passage of the wick 20.

The working liquid liquefied in the condensation portion 6 flows in the flow passage of the wick 20 and is refluxed to the evaporation portion 4 through the intermediate portion 5 from the condensation portion 6.

As described above, with the circulation of the working fluid in the accommodation portion 31 including the wick 20, the heat from the electrical connection portion 32 can be transferred to the first end part la of the heat pipe 1.

In the above description, only the transfer of the heat generated on the connection surface between the first member 110 and the electrical connection portion 32 has been described. In a case where there is a temperature difference between the end part of the accommodation portion 31 on the side in the −X direction and the end part of the accommodation portion 31 on the side in the +X direction, the heat transfer by the working fluid is performed in the accommodation portion 31. That is, the heat generated in the electrical connection portion 32 moves toward the accommodation portion 31 having a lower temperature than the electrical connection portion 32, and the heat is further transferred in the +X direction having a lower temperature in the accommodation portion 31 by the working fluid in the accommodation portion 31. Therefore, in the electrical connection portion 32, the heat generated on the connection surface between the second member 120 and the electrical connection portion 32 is also transferred toward the first end part la of the heat pipe 1 by the working fluid in the accommodation portion 31.

Further, the entire surface of the electrical connection portion 32 is made of metal in the cross section orthogonal to the longitudinal direction X, whereas the wall thickness L of the container 30 in the accommodation portion 31 is, for example, about 0.2 mm, which is very small. Since the difference in the thickness of the metal of the container 30 causes large electric resistance, the electric current is less likely to flow in a direction from the electrical connection portion 32 toward the accommodation portion 31. Therefore, the current from the first member 110 can be caused to flow toward the second member 120 via the electrical connection portion 32.

The accommodation portion 31 is provided with the working fluid for the heat transfer and the wick 20, and thermal resistance between the accommodation portion 31 and the electrical connection portion 32 is small. Therefore, the movement of heat is smoothly performed from the electrical connection portion 32 to the accommodation portion 31.

As described above, the heat pipe 1 of one or more embodiments includes the container 30 in which the working fluid is sealed, and the wick 20 accommodated in the container 30, and the container 30 includes the accommodation portion 31 that accommodates the wick 20 and the working fluid, and the electrical connection portion 32 that is disposed at the position different from the accommodation portion 31 in the longitudinal direction

With this configuration, the heat pipe 1 can function as the terminal that electrically connects the first member 110 and the second member 120, and can function as the heat transfer element that transfers the heat of the electrical connection portion 32. That is, with the circulation of the working fluid sealed inside the accommodation portion 31 in contact with the electrical connection portion 32, while the first member 110 and the second member 120 are electrically connected to each other in the electrical connection portion 32, the heat from the electrical connection portion 32 can be efficiently transferred to the first end part la of the heat pipe 1.

Furthermore, in the heat pipe 1 of one or more embodiments, since the electrical connection portion 32 and the accommodation portion 31 are integrally provided in the container 30, the electrical connection portion 32 can be cooled in a more space-saving manner.

Further, the length of the electrical connection portion 32 in the longitudinal direction X is 5 mm or more.

In general, a thickness of the container at an end surface of the heat pipe in the longitudinal direction may be thin in order to reduce the thermal resistance and improve thermal conductivity, and is 5 mm or less. For this reason, in the related art, there is a difficulty in causing the end surface of the heat pipe, which is formed to be so thin, to function as the electrical connection portion. On the contrary, in one or more embodiments, with the ensuring of the length of the electrical connection portion 32 in the heat pipe 1, the first member 110 and the second member 120 can be reliably electrically connected.

### Second Embodiments

Next, second embodiments according to the present invention will be described, but the basic configuration is the same as the configuration of the first embodiments. Thus, the same reference signs are assigned to the same configurations, the description thereof will be omitted, and only a difference will be described.

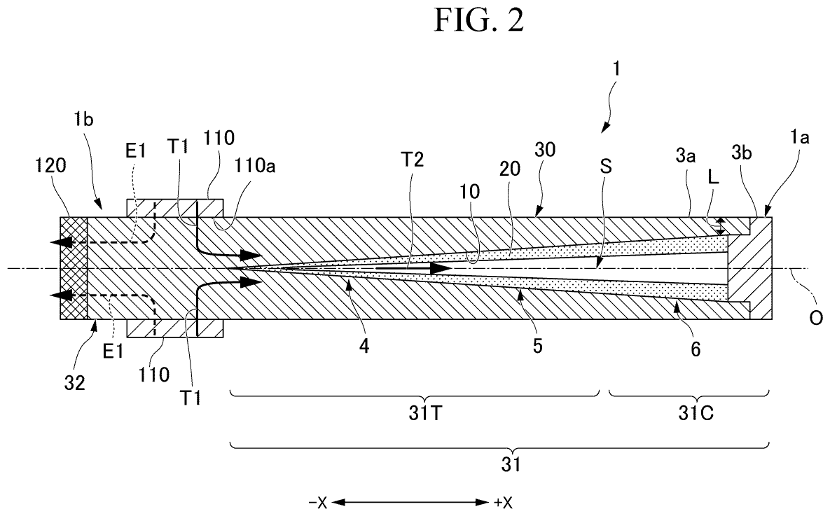

FIG. 2 shows the heat pipe 1 according to the second embodiments. In one or more embodiments, the heat pipe 1 of the second embodiments is different from the heat pipe 1 of the first embodiments in that the diameter of the inner hole 10 of the container 30 is not constant in the longitudinal direction.

As shown in FIG. 2, in the heat pipe 1 of one or more embodiments, in a cross section along the longitudinal direction, an inner surface of the accommodation portion 31 is tapered, and an inner diameter of the inner hole 10 gradually decreases from the first end part la toward the −X direction. Thus, the wall thickness L of the container 30 in the accommodation portion 31 decreases as a distance from the electrical connection portion 32 increases.

Accordingly, since the wall thickness L of the container 30 can be ensured at the end part of the accommodation portion 31 on the side in the −X direction, the movement of heat from the electrical connection portion 32 to the accommodation portion 31 and the movement of heat from

the container 30 to the inside of the inner hole 10 in the heat transfer portion 31T can be more efficiently performed.

Further, in the cross section along the longitudinal direction, the thickness of the wick 20 gradually decreases from the first end part la toward the −X direction. Accordingly, in the evaporation portion 4 and the intermediate portion 5, the internal space S, which is a vapor movement space, can be more reliably ensured.

Further, a cross sectional area of the internal space S of the wick 20 in a transverse section orthogonal to the longitudinal direction X increases as the distance from the electrical connection portion 32 increases. In one or more embodiments, the internal space S of the wick 20 in the transverse section has a circular shape. Thus, a diameter of the internal space S in the transverse section increases as the distance from the electrical connection portion 32 increases. Accordingly, the movement of vapor to the condensation portion 6 can be performed more smoothly.

The technical scope of the present invention is not limited to the embodiments or examples described above, and various changes can be made without departing from the scope of the present invention.

For example, in the above embodiments, the number of the accommodation portions 31 of the heat pipe 1 and the number of the electrical connection portions 32 thereof are each one, but the number of the accommodation portions 31 of the heat pipe 1 may be one or more, and the number of the electrical connection portions 32 thereof may be one or more.

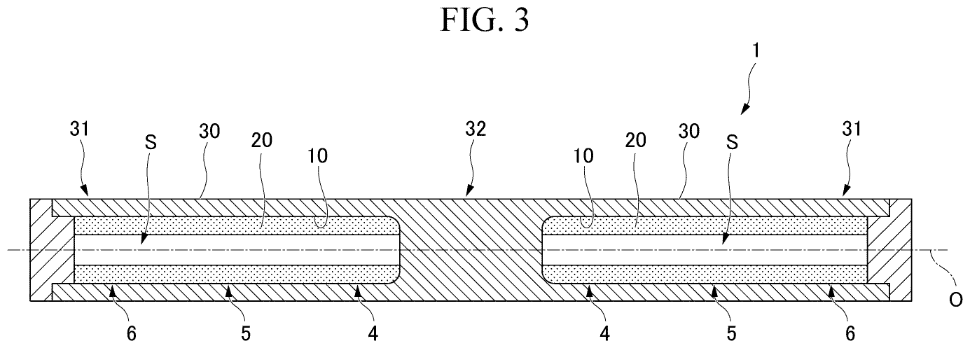

In the example shown in FIG. 3, the heat pipe 1 includes one electrical connection portion 32, and two accommodation portions 31 that interpose the electrical connection portion 32 therebetween. Accordingly, the heat generated in the electrical connection portion 32 can be efficiently moved to both end parts of the heat pipe 1 in the longitudinal direction by the two accommodation portions 31.

Further, the container 30 is not limited to the columnar shape, and may have a quadrangular prism shape or a polygonal prism shape. The container 30 may have a shape in which a column, a quadrangular prism, or a polygonal prism is combined in the longitudinal direction. Further, the shape of the container 30 may be changed as appropriate according to the shapes of the first member 110, the second member 120, and the heat dissipation structure, which are connected to the heat pipe 1.

For example, in a case where a recess portion having a rectangular-shaped opening is formed in the second member 120 and the electrical connection portion 32 is inserted into the recess portion, the electrical connection portion 32 may have the quadrangular prism shape that is fitted into the recess portion. Furthermore, in this case, the electrical connection portion 32 may have the quadrangular prism shape, and the accommodation portion 31 may have the circular shape.

Further, the length of the electrical connection portion 32 in the longitudinal direction X is not limited to 5 mm or more. The length of the electrical connection portion 32 in the longitudinal direction X may be a length that allows a desired electric current to flow appropriately in a case where the two members 110 and 120 are electrically connected. For example, in a case where the second member 120 is a small electronic device that does not require a high electric current, the length of the electrical connection portion 32 in the longitudinal direction X may be 1 mm or less, or may be in a range of 1 to 5 mm. In a case where the second member 120 is a large battery, the length of the electrical connection portion 32 in the longitudinal direction X may be in a range of 5 to 20 mm in order to cause a large electric current to flow.

Further, the length of the electrical connection portion 32 in the longitudinal direction X may be a length that allows the electrical connection portion 32 to be stably fixed to the hole provided in the second member 120. In this case, the heat pipe 1 can be used as a pin-type terminal that is inserted into the hole of the second member 120.

Further, an outer diameter of the electrical connection portion 32 may be such that it allows a desired electric current to flow appropriately in a case where the two members 110 and 120 are electrically connected.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1 heat pipe
20 wick
30 container
31 accommodation portion
32 electrical connection portion
L wall thickness
S internal space
X longitudinal direction

1. A heat pipe comprising:
a container in which working fluid is sealed; and
a wick accommodated in the container, wherein
the container comprises:
an accommodation portion that accommodates the wick and the working fluid; and
an electrical connection portion at a position different from the accommodation portion in a longitudinal direction of the container.

2. The heat pipe according to claim 1, wherein a length of the electrical connection portion in the longitudinal direction is 5 mm or more.

3. The heat pipe according to claim 1, wherein a wall thickness of the container in the accommodation portion decreases as a distance from the electrical connection portion increases.

4. The heat pipe according to claim 1, wherein a cross sectional area of an internal space of the wick in a transverse section orthogonal to the longitudinal direction increases as a distance from the electrical connection portion increases.

5. The heat pipe according to claim 1, wherein an inside of the accommodation portion has a tapered shape in a cross section along the longitudinal direction.
